(19) United States
(12) Patent Application Publication
(10) Pub. No.: US 2026/0352162 A1
(43) Pub. Date: Nov. 5, 2026

(54) TEMPERATURE COMPENSATED OPERATIONAL TRANSCONDUCTANCE AMPLIFIER

(71) Applicant: SEMICONDUCTOR COMPONENTS INDUSTRIES, LLC, Scottsdale, AZ (US)

(72) Inventor: Boncho NIKOV, Marin-Epagnier (CH)

(73) Assignee: SEMICONDUCTOR COMPONENTS INDUSTRIES, LLC, Scottsdale, AZ (US)

(21) Appl. No.: 19/441,456

(22) Filed: Jan. 6, 2026

Related U.S. Application Data
(60) Provisional application No. 63/797,404, filed on Apr. 30, 2025.

(51) Int. Cl. H03F 1/30; H03F 3/45

(52) U.S. Cl. CPC H03F 1/303; H03F 3/45071; H03F 2200/21

(57) ABSTRACT

An operational transconductance amplifier (OTA) design that incorporates temperature compensation to maintain a set transconductance over a wide temperature range. One illustrative circuit includes: an input module and a compensation module. The input module has a differential pair of input transistors configured to operate on a differential input voltage. The compensation module has: a first reference transistor having an operating point approximate to that of the input transistors; a second reference transistor having a shared drain node with the first reference transistor, a shared gate node with the first reference transistor, a channel with a larger width to length ratio than the first reference transistor, and source node connected to a sense resistance; and an error amplifier that adjusts the operating point of the first reference transistor and of the input transistors to have a transconductance based on the sense resistance.

### CROSS REFERENCE TO RELATED APPLICATIONS

The present application claims benefit of provisional U.S. application 63/797,404, filed 2025 Apr. 30 and titled “Constant Transconductance (Gm) Biasing” by inventor Boncho Nikov. The foregoing application is hereby incorporated herein by reference in its entirety.

### TECHNICAL FIELD

The present application relates generally to transconductance amplifiers, and more particularly, to designs and methods for temperature compensation to maintain accurate amplifier performance across a wide temperature range.

### BACKGROUND

Operational amplifiers (“op-amps”) are electronic, high-gain, integrated circuit devices that operate on a differential voltage input. Such devices have many applications and are particularly useful for feedback control loops and active filters, and as such are ubiquitous elements of modern technology. In many cases, the use of operational transconductance amplifiers (OTAs), rather than traditional op-amps, enables the designs of such circuits to operate more efficiently, usually with fewer components and increased reliability.

Rather than straightforward voltage amplification, OTAs provide an output current that is proportional to the input voltage. In other words, within a defined region around its operating point, an OTA operates as a voltage controlled current source. The relationship can be expressed in equation form as

Iₒᵤₜ=(Vᵢₙ₊−Vᵢₙ₋)·gₘ,

where gₘ represents the transconductance.

Notably, n-type and p-type metal oxide semiconductor (NMOS, PMOS) transistors have a transconductance that is highly sensitive to temperature variations and to biasing of the back gate (aka body or bulk bias), creating potential performance issues for OTA designs based on such transistors. Accurate compensation of these effects may complicate the device design and may rely on using pairs of resistors with different temperature coefficients, which can be a challenge when seeking to account for a range of potential manufacturing process variations. Alternative compensation techniques are sought.

### SUMMARY

The foregoing issues are at least in part addressed by an operational transconductance amplifier (OTA) design that incorporates temperature compensation to maintain a set transconductance over a wide temperature range. One illustrative circuit includes: first, second, and third bias transistors, first and second reference transistors, a sense resistance, and an error amplifier. The first bias transistor provides a first current flow through the first reference transistor. The second bias transistor provides a second current flow through the second reference transistor via the sense resistance. Notably, the second reference transistor has a channel width-to-length ratio greater than that of the first reference transistor and has a shared drain node and a shared gate node with the first reference transistor. The third bias transistor provides a third current flow to or from a shared source node of the first input transistor and the second input transistor. The first input transistor has a gate to receive a first input voltage, the second input transistor has a gate to receive a second input voltage, and the second input transistor has a drain connected to an output node to provide an output current proportional to a difference between the first input voltage and the second input voltage. The error amplifier drives the gates of the first bias transistor, the second bias transistor, and the third bias transistor, to a bias voltage that equalizes the drain voltage of the first bias transistor with the drain voltage of the second bias transistor.

An illustrative method includes: providing a first current flow through a first reference transistor with a first bias transistor; providing a second current flow through a second reference transistor via a sense resistance with a second bias transistor, the second reference transistor having a channel width-to-length ratio greater than the first reference transistor and having a shared drain node and shared gate node with the first reference transistor; using a third bias transistor to provide a third current flow to or from a shared source node of a first input transistor and a second input transistor, the first input transistor having a gate configured to receive a first input voltage, the second input transistor having a gate configured to receive a second input voltage, and the second input transistor having a drain connected to an output node to provide an output current proportional to a difference between the first input voltage and the second input voltage; and with an error amplifier, driving gates of the first bias transistor, the second bias transistor, and the third bias transistor, to a bias voltage that equalizes a drain voltage of the first bias transistor to a drain voltage of the second bias transistor.

Another illustrative circuit includes: an input module and a compensation module. The input module has a differential pair of input transistors configured to operate on a differential input voltage. The compensation module has: a first reference transistor having an operating point approximate to that of the input transistors; a second reference transistor having a shared drain node with the first reference transistor, a shared gate node with the first reference transistor, a channel with a larger width to length ratio than the first reference transistor, and source node connected to a sense resistance; and an error amplifier that adjusts the operating point of the first reference transistor and of the input transistors to have a transconductance based on the sense resistance.

The foregoing examples can be employed individually or in conjunction and may include one or more of the following optional features in any suitable combination: 1. a first load resistance configured to couple a first supply voltage to a drain of the first input transistor. 2. a second load resistance configured to couple the first supply voltage to a drain of the second input transistor, the second load resistance matching the first load resistance. 3. a third load resistance configured to couple the first supply voltage to the shared drain node and to sustain a voltage drop that matches a voltage drop across the first load resistance. 4. the first input transistor, the second input transistor, the first reference transistor, and the second reference transistor each have a body node connected to a shared body voltage. 5. the shared body voltage is the source voltage of the differential pair. 6. the shared body voltage is a ground voltage. 7. the first input transistor and the second input transistor each have a body node connected to the shared source node. 8. the shared gate node is biased to a common mode voltage of the first input voltage and the second input voltage.

### BRIEF DESCRIPTION OF THE DRAWINGS

FIG. 1 is a graph of relative transconductance vs temperature for illustrative transistors.

FIG. 2 is a schematic of a first illustrative operational transconductance amplifier

(OTA).

FIG. 3A is a schematic of a first illustrative variable resistor.

FIG. 3B is a schematic of a second illustrative variable resistor.

FIG. 4 is a schematic of an illustrative OTA variation.

FIG. 5 is a graph showing the offsetting of temperature dependences.

FIG. 6 is a graph showing an illustrative temperature compensated transconductance.

### DETAILED DESCRIPTION

The drawings and following description do not limit the disclosure, but on the contrary, they provide the foundation for one of ordinary skill in the art to understand all modifications, equivalents, and alternatives falling within the scope of the claim language.

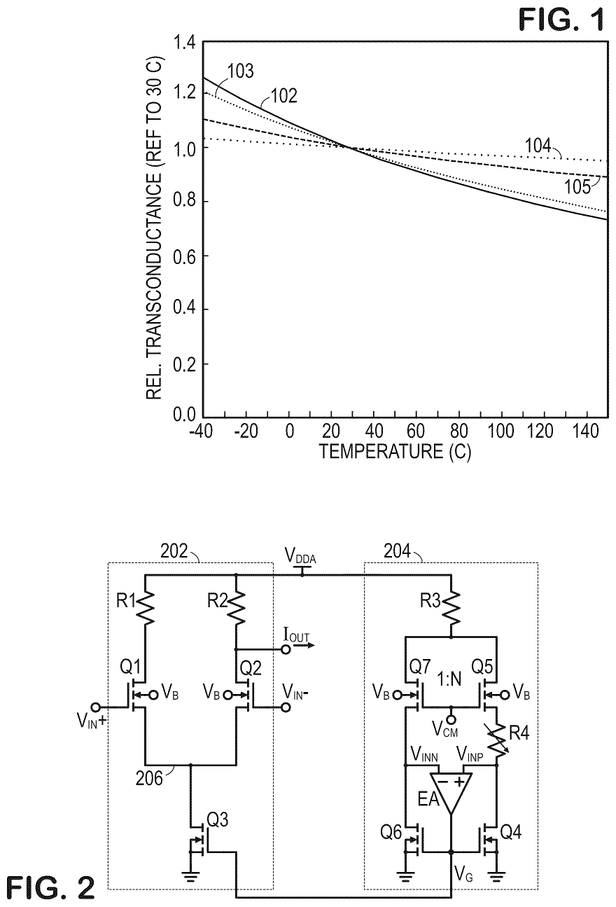

FIG. 1 shows a first curve 102 representing the relative transconductance of an illustrative NMOS transistor. Each of the curves is normalized to unity at 30 °C, and each of the curves is determined for a transistor having a gate-source voltage of 1 volt and a drain-source voltage of 2 volts, a channel width of 5 microns, and a channel length of 1 micron. Curves 102, 103 are for an enhancement mode NMOS transistor with a body-source voltage of 0 volts and −0.3 volts, respectively. Curves 104, 105 are for an enhancement mode PMOS transistor with a body-source voltage of 0 volts and 0.3 volts, respectively.

The transconductance (gₘ) of NMOS and PMOS transistors is highly sensitive to temperature variations. In the temperature range from −40 to 150 °C, curve 102 drops from 1.26 to 0.72, a variation of about 43%. For curve 103, the variation is about 38%. For curve 104, the variation is about 21%, and for curve 105 the variation is about 8.5%. The effect of back gate biasing is notable but may be insufficient in itself to mitigate the temperature dependence of OTAs based on these devices.

FIG. 2 is a schematic of an illustrative OTA that is rendered PVT (Process, Voltage, and Temperature) insensitive, ensuring stable performance across various manufacturing processes, supply voltages, and operating temperatures. To ensure accuracy and consistent performance in real world applications, the design accounts for various effects including finite output resistance, back-gate biasing, and different regions of channel conduction (e.g., impact ionization). Furthermore, the design offers adjustable transconductance, providing flexibility for different application requirements and simplifying the tuning process during design and manufacturing.

The illustrative OTA is a circuit that includes an input module 202 and a compensation module 204. The input module 202 includes a differential pair of input transistors Q1, Q2 having a shared source node 206. Each of the input transistors Q1, Q2 has a drain coupled to a supply voltage V_{DDA} by a respective load resistance R1, R2. Input transistor Q1 has a gate that receives V_{IN}+, the positive side of a differential input voltage ΔV_{IN}=(V_{IN}+)−(V_{IN}−), and input transistor Q2 has a gate that receives V_{IN}−, the negative side of the differential input voltage. The positive side can also be written as V_{IN}+=V_{CM}+ΔV_{IN}/2, where V_{CM} is the common mode voltage, i.e., V_{CM}=[(V_{IN}+)+(V_{IN}−)]/2. The negative side can similarly be written V_{IN}−=V_{CM}−ΔV_{IN}/2. As the bias transistor Q3 draws current from the shared source node 206, the differential input voltage affects the amount of current that is diverted from the output terminal I_{OUT} producing the result

Iₒᵤₜ=gₘΔV_{IN}.

The compensation module 204 controls the current provided by bias transistor Q3 as needed to maintain a transconductance gₘ that is insensitive to temperature.

Compensation module 204 includes a pair of reference transistors Q7, Q5 with respective bias transistors Q6, Q4. Reference transistor Q7 may be configured inasmuch as possible to have the same operating point as each of the input transistors Q1, Q2. Bias transistors Q3, Q6, Q4 may have the same relatively high channel length L with a channel width W that determines the respective bias currents at the expected overdrive voltage. Input transistors Q1, Q2 and reference transistors Q5, Q7 may have a relatively short channel length L to support current flow at a lower overdrive voltage, with channel widths chosen to match quiescent current flow to the bias transistor currents. (As discussed below, reference transistor Q5 preferably has a larger channel width than reference transistor Q7.) The load resistances R1, R2, R3 are sized to provide an equal voltage drop under quiescent current flow conditions.

Reference transistor Q5 has a shared drain node with reference transistor Q7 and has a channel width-to-length ratio that is a factor of N larger than that of reference transistor Q7. The factor N is often an integer, but this is not a requirement. Typically, the channel lengths would be kept equal and the channel width of transistor Q5 would be N times the channel width of transistor Q7. The gates of both reference transistors Q7, Q5 are biased to the common mode voltage V_{CM}. Transistor Q5's larger channel geometry supports the bias current I_{B} with a lower gate to source voltage Vos than that needed by transistor Q7. This difference may be expressed as ΔV_{GS}=V_{GS,7}−V_{GS,5}.

An error amplifier (EA) amplifies the difference between the drain voltages of the bias transistors Q4, Q6, raising the gate voltage V_{G} of the bias transistors until the voltage across the sense resistance R4 matches ΔV_{GS}, the difference in gate-source voltages of the reference transistors Q5, Q7. At this point the drain voltages of the bias transistors Q4, Q6 are equalized and the voltage across the sense resistance is

I_{B}R₄=ΔV_{GS}.

If the reference transistors are operating in the weak inversion region,

ΔV_{GS}≈nV_{T} log N,

where n is the subthreshold slope factor of the drain current, VT is the thermal potential, and N is the factor between channel to width ratios of the reference transistors. At this operating point, any further change in the gate-source voltage produces a change in bias current determined by the ratio of ΔV_{GS} to the sense resistance. In other words, the transconductance of reference transistor Q7 is:

$${g}_{m} \approx \frac{n {V}_{T} log N}{{R}_{4}} .$$

So long as a precise, zero temperature coefficient (0 TC) resistor is used as the sense resistance R4, the transconductance of reference transistor Q7 is maintained at a value that is insensitive to temperature.

Compensation module 204 applies the gate voltage V_{G} of the bias transistors to bias transistor Q3, providing a current mirror that places the input transistors Q1, Q2 at the same operating point as reference transistor Q7, thus ensuring the input module 202 operates with a temperature-insensitive transconductance. The transconductance is proportional to the inverse value of the sense resistance R4. The sense resistance R4 may be implemented as a digital variable resistor to make the transconductance of the illustrative OTA adjustable.

We observe here that the reference and input transistors need not be operated in the weak inversion region—the temperature insensitivity is preserved in other operating regions including the strong inversion region. The effect of finite load resistances are also accounted for. Since the operating points are the same (VGS,VDS,VBS are the same), the effects of finite load resistance, operating region, process variations, voltage variations, negative/positive bias temperature instability (NBTI/PBTI), etc., will the same for both the input transistors and the reference transistors.

Each of the transistors Q1-Q7 is shown as an enhancement mode NMOS with an accessible back gate (“body”) node. The bias transistors Q3, Q4, Q6 may have their body nodes coupled to their source nodes. To account for back gate biasing effects, the input transistors Q1, Q2 and reference transistors D5, Q7 have each of their body nodes coupled to the same back gate voltage V_{B}. In some contemplated implementations, the back gate voltage V_{B} is provided by the shared source node 206. Alternatively, the back gate voltage V_{G} may be coupled to V_{SS}, which in this example is the ground node. Other shared voltage references could alternatively be used for the back gate voltage.

The enhancement mode NMOS transistors are shown for illustrative purposes. The same principles apply when the design is adapted to use PMOS and/or depletion mode transistors.

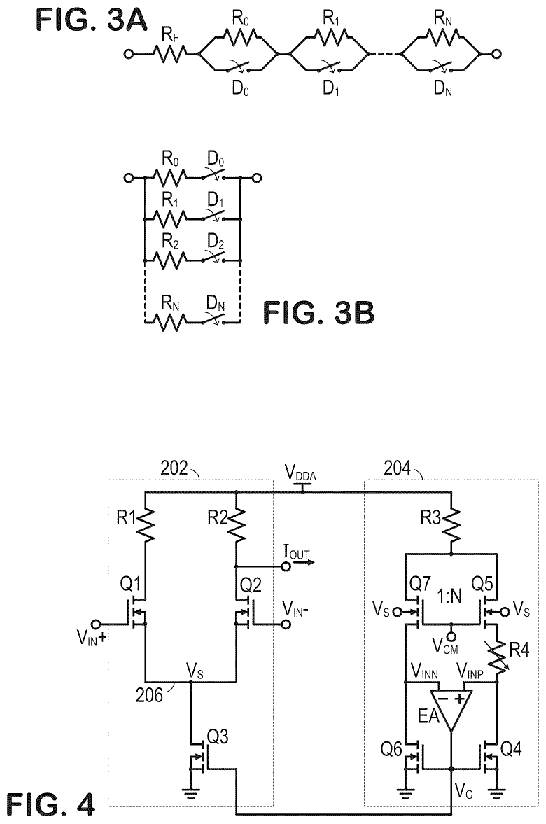

The transconductance gₘ of the OTA is inversely proportional to the sense resistance R4, which can be implemented as a variable resistor to make the transconductance easily adjustable. FIG. 3A shows a first illustrative variable resistor implementation having two end terminals coupled via a series arrangement of a foundation resistor RF with individually bypass-able resistors R0, R1, . . . . RN. Each of the bypass-able resistors has a bypass path that can be enabled or disabled by a switch. The control signal for each switch is a binary value labeled D0, D1, . . . , DN. The switches may be implemented as transistors. The resistors may have equal values, but more efficient implementations may employ differently weighted resistances (e.g., binary weighting) to provide a greater number of programmable values with a smaller number of resistors and control signals.

FIG. 3B shows a second illustrative variable resistor implementation having two end terminals coupled via a parallel arrangement of resistors R0, R1, R2, . . . . RN. Each of the resistors is in series with a switch that can enable or disable current flow through that resistor. As with FIG. 3A, each switch has a binary control signal labeled D0, D1, D2, . . . . DN. Again, the resistors may have equal values, but different weightings may be preferred to provide a greater number of programmable conductance values for a given number of components.

FIG. 4 shows a variation of the FIG. 2 OTA in which the shared body node voltage V_{B} is Vs, the voltage of the shared source terminal 206.

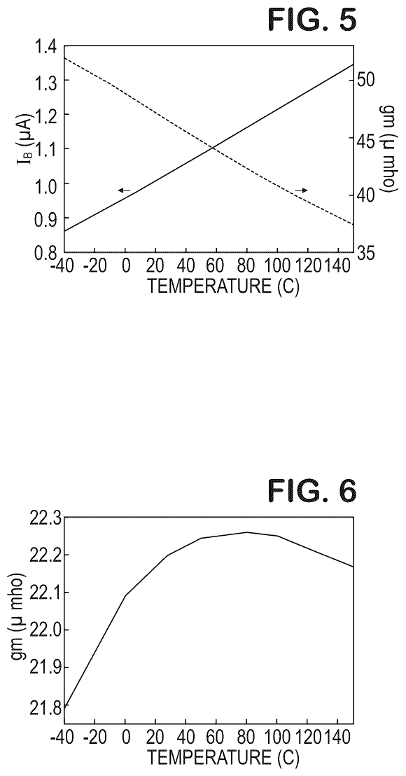

FIG. 5 is a graph that shows the transconductance (dashed line) of an illustrative reference transistor Q7 as a function of temperature. If the drain-source current is held constant, the transconductance falls dramatically as the temperature increases. Such a decrease would reduce the OTA response, diminishing the performance of the control loop or other system at higher temperatures. The compensation module 204 drives the bias current I_{B} upward to maintain the OTA responsiveness as the temperature increases. At least in the region of interest, the bias current is Proportionate To Absolute Temperature (PTAT). For a simulated implementation, the result is that the OTA maintains a relatively constant transconductance as shown by the curve in FIG. 6. In this example, the transconductance is kept within 1.8% of its room temperature value.

Contemplated uses of the disclosed OTA include DC-DC control loops, active filters, and sigma-delta converters, each of which may be expected to show enhanced accuracy that is maintained over a wide temperature range.

While the dependent claims below are written to refer to a single claim as a matter of claim drafting prescriptions in certain countries, it is observed that any combination of a dependent claim with any of its preceding claims is foreseen by the present inventors and is deemed included in the full disclosure of the present application. Furthermore, it is to be understood that the dependent claims depending from a given base claim will also be applicable to the other independent claims but have merely been omitted for the sake of limiting the overall number of claims and any claim fees that may be due as a result thereof.

What is claimed is:

1. A circuit that comprises:
a first bias transistor configured to provide a first current flow through a first reference transistor;
a second bias transistor configured to provide a second current flow through a second reference transistor and a sense resistance connected between the second bias transistor and the second reference transistor, the second reference transistor having a channel width-to-length ratio greater than the first reference transistor and having a shared drain node and shared gate node with the first reference transistor;
a third bias transistor configured to provide a third current flow to or from a shared source node of a first input transistor and a second input transistor, the first input transistor having a gate configured to receive a first input voltage, the second input transistor having a gate configured to receive a second input voltage, and the second input transistor having a drain connected to an output node to provide an output current proportional to a difference between the first input voltage and the second input voltage; and
an error amplifier configured to drive gates of the first bias transistor, the second bias transistor, and the third bias transistor, to a bias voltage that equalizes a drain voltage of the first bias transistor to a drain voltage of the second bias transistor.

2. The circuit of claim 1, further comprising:
a first load resistance configured to couple a first supply voltage to a drain of the first input transistor; and
a second load resistance configured to couple the first supply voltage to a drain of the second input transistor, the second load resistance matching the first load resistance.

3. The circuit of claim 2, further comprising:
a third load resistance configured to couple the first supply voltage to the shared drain node and to sustain a voltage drop that matches a voltage drop across the first load resistance.

4. The circuit of claim 1, wherein the first input transistor, the second input transistor, the first reference transistor, and the second reference transistor each have a body node connected to a shared body voltage.

5. The circuit of claim 4, wherein the shared body voltage is a voltage of the shared source node.

6. The circuit of claim 4, wherein the shared body voltage is a ground voltage.

7. The circuit of claim 1, wherein the shared gate node is biased to a common mode voltage of the first input voltage and the second input voltage.

8. A method that comprises:
providing a first current flow through a first reference transistor with a first bias transistor;
providing a second current flow through a second reference transistor via a sense resistance with a second bias transistor, the second reference transistor having a channel width-to-length ratio greater than the first reference transistor and having a shared drain node and shared gate node with the first reference transistor;
using a third bias transistor to provide a third current flow to or from a shared source node of a first input transistor and a second input transistor, the first input transistor having a gate configured to receive a first input voltage, the second input transistor having a gate configured to receive a second input voltage, and the second input transistor having a drain connected to an output node to provide an output current proportional to a difference between the first input voltage and the second input voltage; and
with an error amplifier, driving gates of the first bias transistor, the second bias transistor, and the third bias transistor, to a bias voltage that equalizes a drain voltage of the first bias transistor to a drain voltage of the second bias transistor.

9. The method of claim 8, further comprising:
loading a drain of the first input transistor with a first load resistance coupled to a first supply voltage; and
loading a drain of the second input transistor with a second load resistance coupled to the first supply voltage, the second load resistance matching the first load resistance.

10. The method of claim 9, further comprising:
loading the shared drain node with a third load resistance coupled to the first supply voltage and configured to sustain a voltage drop that matches a voltage drop across the first load resistance.

11. The method of claim 8, wherein the first input transistor, the second input transistor, the first reference transistor, and the second reference transistor each have a body node connected to a shared body voltage.

12. The method of claim 11, wherein the shared source node provides the shared body voltage.

13. The method of claim 11, wherein the shared body voltage is a ground voltage.

14. The method of claim 8, wherein the shared gate node is biased to a common mode voltage of the first input voltage and the second input voltage.

15. A circuit that comprises:
an input module having a differential pair of input transistors configured to operate on a differential input voltage; and
a compensation module having:
a first reference transistor configured to have an operating point approximate to that of the input transistors;
a second reference transistor having a shared drain node with the first reference transistor, a shared gate node with the first reference transistor, a channel with a larger width to length ratio than the first reference transistor, and source node connected to a sense resistance; and
an error amplifier configured to adjust the operating point of the first reference transistor and of the input transistors to have a transconductance based on the sense resistance.

16. The circuit of claim 15,
wherein the compensation module includes: a first bias transistor configured to provide a first current flow through the first reference transistor, and a second bias transistor configured to provide a second current flow through the second reference transistor and the sense resistance;
wherein the input module includes: a third bias transistor configured to provide a third current flow to or from the differential pair; and
wherein the error amplifier drives a gate voltage of each of the first, second, and third bias transistors based on a difference between a drain voltage of the first bias transistor and a drain voltage of the second bias transistor.

17. The circuit of claim 15, wherein the input module includes for each of the input transistors a first load resistance configured to couple a first supply voltage to a drain of the input transistor; and wherein the compensation module includes: a third load resistance configured to couple the first supply voltage to the shared drain node and to sustain a voltage drop that matches a voltage drop across the first load resistance.

18. The circuit of claim 17, wherein the input transistors, the first reference transistor, and the second reference transistor each have a body node connected to a shared body voltage.
